(19) United States
(12) Patent Application Publication
(10) Pub. No.: US 2018/0096844 A1
(43) Pub. Date: Apr. 5, 2018

(54) METHOD OF GAS-PHASE DEPOSITION BY EPITAXY

(71) Applicants: STMicroelectronics SA, Montrouge (FR); STMicroelectronics (Crolles 2) SAS, Crolles (FR)

(72) Inventors: Didier Dutartre, Meylan (FR); Victorien Paredes-Saez, Lumbin (FR)

(73) Assignees: STMicroelectronics SA, Montrouge (FR); STMicroelectronics (Crolles 2) SAS, Crolles (FR)

(21) Appl. No.: 15/594,763

(22) Filed: May 15, 2017

(30) Foreign Application Priority Data
Oct. 5, 2016 (FR) 1659611

(51) Int. Cl. H01L 21/02; C30B 25/10; C30B 25/14; C30B 25/02

(52) U.S. Cl. CPC H01L 21/02381; H01L 21/0245; H01L 21/02496; C30B 25/02; H01L 21/0262; C30B 25/10; C30B 25/14; H01L 21/0237

(57) ABSTRACT

A gas phase epitaxial deposition method deposits silicon, germanium, or silicon-germanium on a single-crystal semiconductor surface of a substrate. The substrate is placed in an epitaxy reactor swept by a carrier gas. The substrate temperature is controlled to increase to a first temperature value. Then, for a first time period, at least a first silicon precursor gas and/or a germanium precursor gas introduced. Then, the substrate temperature is decreased to a second temperature value. At the end of the first time period and during the temperature decrease, introduction of the first silicon precursor gas and/or the introduction of a second silicon precursor gas is maintained. The gases preferably have a partial pressure adapted to the formation of a silicon layer having a thickness smaller than 0.5 nm.

### PRIORITY CLAIM

This application claims the priority benefit of French Application for Patent No. 1659611, filed on Oct. 5, 2016, the disclosure of which is hereby incorporated by reference in its entirety.

### TECHNICAL FIELD

The present disclosure relates to a method of depositing by epitaxy a semiconductor material and more particularly the deposition of single-crystal silicon-germanium on single-crystal silicon or single-crystal silicon-germanium surfaces.

### BACKGROUND

FIGS. 1A and 1B illustrate a conventional method of selective deposition by gas phase heteroepitaxy of silicon-germanium on regions formed on a silicon wafer. FIG. 1A shows, in a timing diagram 10, the temperature variation of the wafer during the process. FIG. 1B shows, in a timing diagram 20, the different gases present in an epitaxy reactor during the process.

During a method of selective deposition by gas phase heteroepitaxy, the wafer where the deposition is desired to be performed is arranged in an epitaxy reactor. An epitaxy reactor is an enclosure where one or a plurality of gases are injected and pumped out to control the gas pressure in the epitaxy reactor. An epitaxy reactor is equipped with a susceptor having the wafer arranged thereon. A susceptor is a support having its temperature controlled by the user. All along the process, a carrier gas 22 flows in the epitaxy reactor. A method of selective deposition by gas phase heteroepitaxy of a semiconductor, for example, silicon-germanium, on the surface of a wafer, for example, made of silicon, comprises three main successive steps.

The first step is a step of heating the susceptor and thus the wafer. Timing diagram 10 shows that, between times t0 and t1, the temperature of the susceptor and of the wafer is taken to and held at a deposition temperature Td. The wafer may be submitted to a cleaning anneal during the heating period. In this case, the temperature is increased up to a temperature higher than deposition temperature Td (this is illustrated by the curve portion in dotted lines 12). Such a cleaning anneal may further enable to accelerate the heating up.

The second step is an epitaxial deposition step. Timing diagram 20 shows that, between time t1 and a time t2, gases 24 capable of generating a selective deposition are introduced into the epitaxy reactor. Gases 24 comprise precursor gases for the deposition of the single-crystal semiconductor, for example precursor gases for the deposition of silicon and germanium, and gases capable of etching the silicon. The susceptor temperature is maintained at value Td and deposition gases 24 enable to perform the deposition on a silicon surface while avoiding a deposition on all the other wafer portions. The value of deposition temperature Td is selected among others according to the deposition gases 24 used and to the desired composition of the deposit. As an example, to perform a silicon-germanium deposition, the deposition gases may be dichlorosilane (Si₂H₂Cl₂) and germane (GeH₄). Hydrogen chloride (HCl) is currently introduced during the deposition phase, to make the deposition selective. This enables to form an epitaxial deposit on exposed single-crystal silicon surfaces and to prevent a deposition on surfaces masked, for example, with silicon oxide.

The third step is a step of purging the epitaxy reactor and of cooling the susceptor. Timing diagram 20 shows that, after time t2, deposition gases 24 stop being introduced into the epitaxy reactor. The deposition gases remaining in the epitaxy reactor are drained off by pumping. Then, the temperature of the susceptor, and thus of the wafer, is lowered or the wafer is discharged, which also results in cooling said wafer.

FIG. 2 is a cross-section view illustrating an epitaxial structure 30. As an example, structure 30 comprises silicon-germanium on silicon. The heteroepitaxial growth occurs on a region 32, for example, made of silicon, surrounded with an insulating region 34, for example, made of silicon oxide. Surface 35 of region 32 has an epitaxial deposit 36, for example, made of silicon-germanium, resting thereon. Epitaxial deposit 36 generally laterally continues on insulating area 34 by lateral growth generally in the range from 0.3 to 1 times the value of the deposit thickness. The deposit has a thickness, for example, in the range from 4 to 25 nm. The deposition may be carried out by a gas phase epitaxy deposition method, as described in relation with FIGS. 1A and 1B. Although, in FIG. 2, semiconductor deposit 36 has a rectangular cross-section and a planar upper surface, the deposit may in practice be faceted with non-vertical facets, for example, inclined, of {111} type (orientation).

FIG. 3 is a cross-section view of an epitaxial structure 40 formed on a region 32 having small dimensions. It can indeed be observed that, when dimension L is decreased down to a value smaller than 30 nm, epitaxial deposit 36 no longer has the shape of a straight stud, possibly faceted, but of a stud with rounded angles, and may even reach a more or less spherical shape. Such rounding phenomena have disadvantages for the subsequent manufacturing steps.

### SUMMARY

Thus, an embodiment provides a method of gas phase epitaxial deposition of silicon, of germanium, or of silicon-germanium on a single-crystal semiconductor surface of a substrate, the method comprising successive steps of: placing the substrate in an epitaxy reactor swept by a carrier gas; taking the substrate temperature to a first value; introducing, for a first time period, at least a first silicon precursor gas and/or a germanium precursor gas; and decreasing the substrate temperature down to a second value, the method comprising, after the first time period and during the temperature decrease step, maintaining the introduction of the first silicon precursor gas and/or the introduction of a second silicon precursor gas, said gases having a partial pressure adapted to the forming of a silicon layer having a thickness smaller than 0.5 nm.

According to an embodiment, the substrate surface is made of silicon.

According to an embodiment, the carrier gas is an inert gas.

According to an embodiment, the carrier gas is one of hydrogen, dinitrogen, helium, or a rare gas.

According to an embodiment, the first and/or second silicon precursor gases are selected from silane, disilane, dichlorosilane, trichlorosilane or silicon tetrachloride.

According to an embodiment, the germanium precursor gas is selected from germane and digermane.

According to an embodiment, the method comprises a deposition by selective epitaxy during which a gas capable of etching silicon is introduced during the first time period.

According to an embodiment, the gas capable of etching silicon is selected from hydrogen chloride or gaseous chlorine.

According to an embodiment, the method comprises depositing by gas phase epitaxy silicon-germanium on a surface of a silicon substrate having a lateral dimension smaller than 40 nm formed on a silicon region, said method comprising successive steps of: placing the substrate in an epitaxy reactor swept by hydrogen; taking the substrate temperature to a first value; introducing dichlorosilane, germane, and hydrogen chloride for a first time period; and decreasing the substrate temperature down to a second value, the method comprising, after the first time period and during the temperature decrease phase, maintaining the introduction of dichlorosilane.

According to an embodiment, the silicon-germanium has a germanium concentration greater than 35%.

According to an embodiment, the silicon-germanium deposit has a thickness in the range from 4 to 25 nm.

According to an embodiment, the hydrogen is introduced into the epitaxy reactor, at a flow rate in the range from 40 to 50 standard liters per minute, the dichlorosilane is introduced at a flow rate in the range from 0.06 to 0.3 standard liter per minute, for example, in the order of 0.1 standard liter per minute, the germane is introduced at a flow rate in the range from 0.006 to 0.03 standard liter per minute, for example, in the order of 0.01 standard liter per minute, and the hydrogen chloride is introduced at a flow rate in the range from 0.01 to 0.1 standard liter per minute, for example, in the order of 0.06 standard liter per minute.

According to an embodiment, the first temperature value is in the range from 650 to 750° C.

According to an embodiment, the second temperature value is in the range from 400 to 650° C.

According to an embodiment, the silicon or the silicon-germanium is boron-doped in situ by using diborane.

According to an embodiment, the silicon or the silicon-germanium is doped in situ with a negative-type dopant by using phosphine or arsine.

According to an embodiment, the epitaxial deposit is made of an alloy of silicon-germanium-carbon.

Another embodiment provides a structure obtained by implementing the previously-described method.

According to an embodiment, the structure is obtained by heteroepitaxy and comprises a silicon-germanium deposit on a silicon surface having a lateral dimension smaller than 40 nm of a substrate, the deposit having a lateral dimension smaller than 40 nm and being faceted, with no rounding of the facet angles.

### BRIEF DESCRIPTION OF THE DRAWINGS

The foregoing and other features and advantages will be discussed in detail in the following non-limiting description of specific embodiments in connection with the accompanying drawings, wherein:

FIGS. 1A and 1B, previously described, show timing diagrams illustrating a heteroepitaxy deposition method;

FIG. 2, previously described, is a cross-section view of a heteroepitaxial structure;

FIG. 3, previously described, is a cross-section view of another heteroepitaxial structure;

FIGS. 4A and 4B show two timing diagrams illustrating an embodiment of a heteroepitaxy deposition method; and

FIG. 5 is a graph illustrating the shape of the deposition formed with the method of FIG. 4.

### DETAILED DESCRIPTION

The same elements have been designated with the same reference numerals in the different drawings. For clarity, only those steps and elements which are useful to the understanding of the described embodiments have been shown and are detailed.

In the following description, unless otherwise specified, expression “in the order of” means to within 10%, preferably to within 5%.

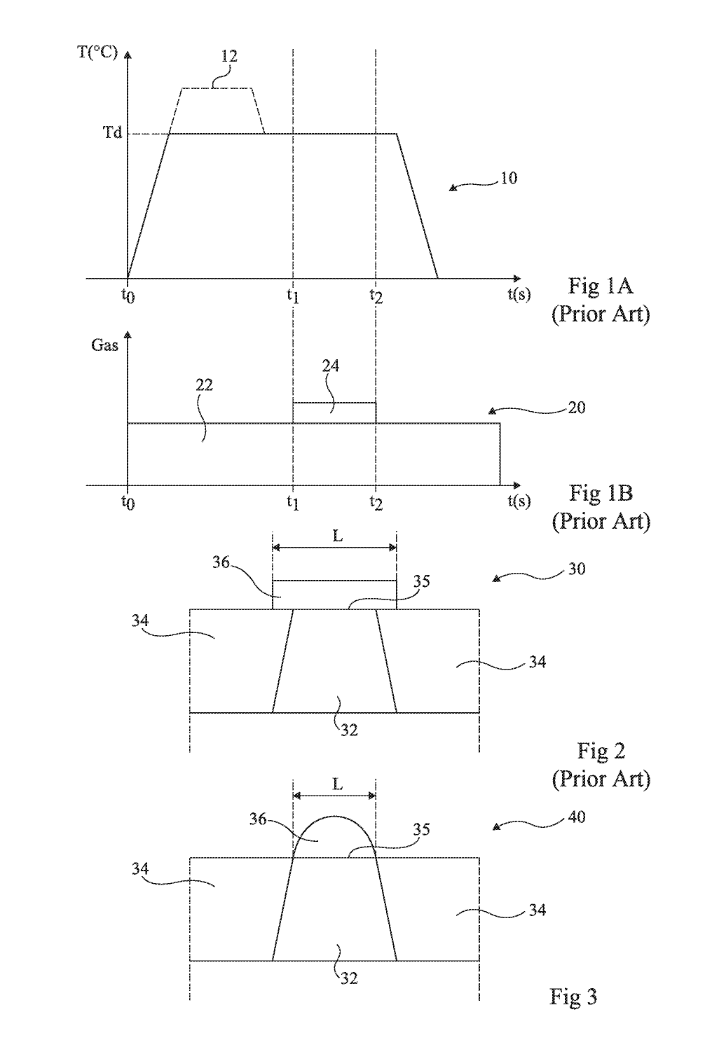

An embodiment of a method of gas-phase epitaxial deposition of silicon, of germanium, or of silicon-germanium on a semiconductor substrate, for example, silicon or silicon-germanium is here provided. This method comprises the same steps as the method described in relation with FIGS. 1A and 1B, but for the fact that certain deposition gases are kept in the epitaxy reactor after the actual epitaxy phase. Gases 24 comprise, for example, precursor gases for the deposition of silicon, precursor gases for the deposition of germanium, and gases capable of etching silicon. The gases which are desired to be kept are, for example, called active gases hereafter. The active gases comprise precursor gases for the deposition of silicon and gases capable of etching silicon. It will be within the abilities of those skilled in the art to determine the partial pressures of active gases to be introduced so as to form a silicon layer having a thickness which remains lower than 0.5 nm.

Precursor gases for the deposition of silicon are, for example, silane (SiH₄), disilane (Si₂H₆), trisilane (Si₃H₈), dichlorosilane (SiH₂Cl₂), trichlorosilane (SiHCl₃), silicon tetrachloride (SiCl₄), or any other known precursor. Precursor gases for the deposition of germanium are for example germane or digermane (Ge₂H₆), or any other known precursor. Gases capable of etching silicon are for example hydrogen chloride (HCl) or gaseous chlorine (Cl₂).

As an example, for a case of epitaxial deposition of silicon-germanium on silicon in the presence of dichlorosilane (SiH₂Cl₂), of germane (GeH₄), and of hydrogen chloride (HCl), the carrier gas being hydrogen (H₂), the active gases are dichlorosilane and possibly hydrogen chloride.

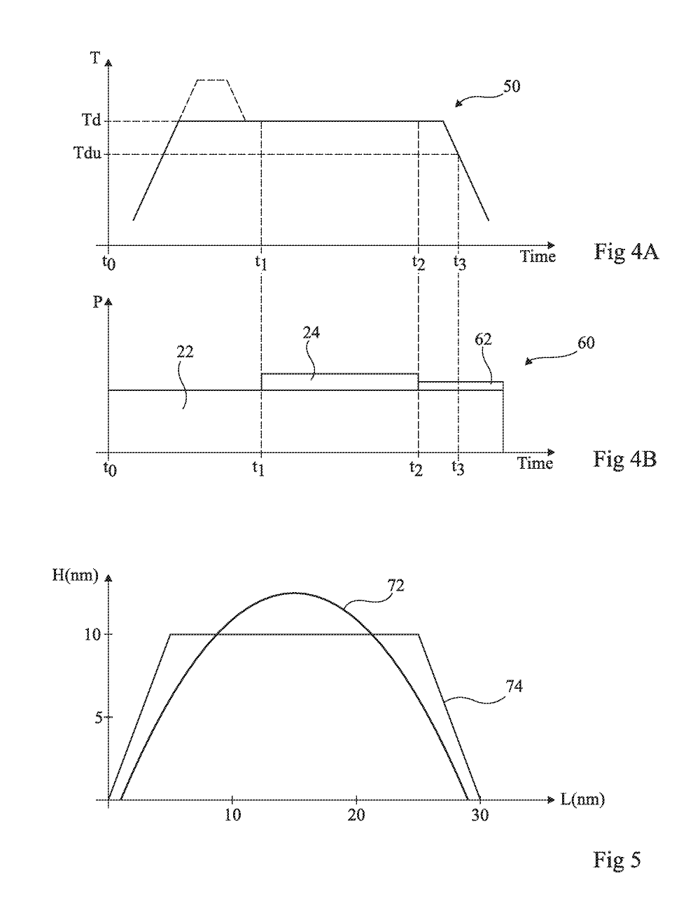

FIG. 4A shows, in a timing diagram 50, the temperature variation during the process. FIG. 4B shows, in a timing diagram 60, the different gases flowing through the epitaxy reactor during the process.

This embodiment comprises the successive steps of:
between times t0 and t1, increasing the susceptor temperature up to deposition temperature Td;
between times t1 and t2, introducing deposition gases 24;
between time t2 and a time t3, maintaining the above-mentioned active gases 62 and decreasing the temperature down to a temperature Tdu at which the surface mobility of silicon or germanium atoms becomes negligible and the shape of the epitaxial structure is no longer capable of deforming under the action of temperature; and
after time t3, purging the reactor and ventilating when the wafer temperature reaches a sufficiently low temperature.

As an example, to obtain a silicon-germanium deposit having, for example, a germanium concentration greater than 35%, the following pressure and flow rate values are selected. The total pressure of the gases in the epitaxy reactor is in the order of 2,600 Pa (20 torr). The hydrogen may be introduced into the epitaxy reactor at a flow rate in the range from 30 to 40 slm (standard liters per minute, liter at standard pressure and temperature conditions, that is, for a 1-bar pressure and a 25° C. temperature). The dichlorosilane is introduced, for example, at a flow rate in the order of 0.1 slm. The germane is introduced, for example, at a flow rate in the order of 0.01 slm. The hydrogen chloride is introduced, for example, at a flow rate in the order of 0.05 slm. Deposition temperature Td is in the range from 650 to 750° C., for example, 620° C. The duration of the deposition phase t2-t1 is, for example, in the order of 300 s for a deposit having a thickness in the order of 20 nm. Temperature Tdu is in the range from 400 to 650° C., for example, in the order of 500° C.

In the case where a silicon-germanium deposit doped with boron atoms is desired to be formed, a gas containing boron atoms, such as diborane (B₂H₆), is added to deposition gases 24. The diborane may be introduced into the epitaxy reactor at a flow rate selected according to the flow rates of the other deposition gases, such a selection being within the abilities of those skilled in the art. In this case, a deposition temperature Td in the order of 610° C. is for example selected. In these conditions, a deposition of boron-doped silicon-germanium is performed with a dopant atom concentration in the range from 10¹⁹ to 5×10²⁰ atoms/cm³, for example, in the order of 4×10²⁰ atoms/cm³.

FIG. 5 shows profiles of studs 72 and 74 respectively obtained by the method of FIGS. 1A and 1B and by that of FIGS. 4A and 4B, in the case of studs having lateral dimensions smaller than 30 nm. The axis of abscissas represents a lateral dimension L of the stud and the axis of ordinates represents thickness H of the stud. These two dimensions are expressed in nm. Profile 72 has a more or less semi-circular shape like the stud described in relation with FIG. 3. Profile 74 has a substantially planar upper surface like the large stud described in relation with FIG. 2. This upper surface has a radius of curvature greater than 4 times the width of the pattern and/or a RA roughness smaller than 0.5 nm rms (root mean square) after correction of the main curvature.

Such a satisfactory result can be expressed as follows. The thermal rounding phenomenon would be the result of the surface tension of the silicon (or silicon-germanium or germanium) surface and of the mobility of silicon (and/or germanium) atoms after the actual deposition phase. The effect of this phenomenon very strongly increases when dimension L becomes smaller than 30 nm. There would seem that after time t2, once the epitaxial deposition phase is over, the shape of the deposition is identical to that described in relation with FIG. 2, whatever the value of dimension L. It is considered that the degradation of the stud shape appears during the third phase of the method. The silicon (and/or germanium) atoms of the silicon-germanium stud would have a certain surface mobility once the deposition is completed, that is, after time t2. Since the surface mobility decreases as the temperature decreases, the stud would stop deforming once a temperature Tdu has been reached. The introduction of the active gases during this phase would generate a phenomenon of adsorption of atoms of the active gases at the surface of the deposit. The silicon atoms of the deposit would be immobilized by the atoms, generally chlorine and/or hydrogen, originating from the active gases coupling to their dangling bonds. Thus, the stud can no longer degrade. However, since the presence of germanium favors the desorption of chlorine and hydrogen atoms and decreases the quantity of adsorbed radicals, germane thus does not belong to the active gases. The rearrangement of the semiconductor crystal atoms, at high deposition temperatures, by surface mobility, would decrease the surface energy of epitaxial structures of small dimensions. This same surface mobility at high temperature would further be implemented during the forming of Stranski-Krastanov islands which affect planar epitaxial surfaces in the presence of mechanical stress. These islands are local unevennesses of the deposit thickness.

The presence of precursor gases for the deposition of silicon may favor the deposition of a silicon layer, having a thickness smaller than 0.5 nm, at the surface of the deposit. The layer will be removed by different cleanings which conventionally follow epitaxial deposition methods.

Specific embodiments have been described. Various alterations and modifications will occur to those skilled in the art. In particular, this method is also efficient to suppress Stranski-Krastanov islands.

Further, the silicon or the silicon-germanium may be doped in situ with a negative-type dopant by using phosphine or arsine.

Further, the epitaxial deposit may be made of an alloy of silicon-germanium-carbon (SiGeC).

1. A method of gas phase epitaxial deposition of a semiconductor material made of one of silicon, germanium, or silicon-germanium on a single-crystal semiconductor surface of a substrate, the method comprising successive steps of:
placing the substrate in an epitaxy reactor swept by a carrier gas;
bringing the substrate temperature to a first temperature value;
introducing, for a first time period, at least a first precursor gas selected from the group consisting of: a silicon precursor gas and a germanium precursor gas; and
decreasing the substrate temperature down to a second temperature value,
after the first time period, maintaining the introduction of at least the first precursor gas having a partial pressure adapted to the forming of a silicon layer having a thickness smaller than 0.5 nm.

2. The method of claim 1, wherein a surface of the substrate is made of silicon.

3. The method of claim 1, wherein the carrier gas is an inert gas.

4. The method of claim 3, wherein the carrier gas is selected from the group consisting of: hydrogen, dinitrogen, helium, and a rare gas.

5. The method of claim 1, wherein the silicon precursor gas is selected from the group consisting of: silane, disilane, dichlorosilane, trichlorosilane, and silicon tetrachloride.

6. The method of claim 1, wherein the germanium precursor gas is selected from the group consisting of: germane and digermane.

7. The method of claim 1, further comprising depositing by selective epitaxy during which a gas capable of etching silicon is introduced during the first time period.

8. The method of claim 7, wherein the gas capable of etching silicon is selected from the group consisting of: hydrogen chloride and gaseous chlorine.

9. A method of gas phase epitaxial deposition of a semiconductor material made of one of silicon, germanium, or silicon-germanium on a surface of a silicon single-crystal semiconductor substrate, said surface having a lateral dimension smaller than 40 nm formed on a silicon region, the method comprising successive steps of:
placing the silicon single-crystal semiconductor substrate in an epitaxy reactor swept by hydrogen;
bringing the silicon single-crystal semiconductor substrate temperature to a first temperature value;
introducing, after a first time period, dichlorosilane, germane, and hydrogen chloride; and
decreasing the silicon single-crystal semiconductor substrate temperature down to a second temperature value, and
at the end of the first time period, maintaining the introduction of dichlorosilane.

10. The method of claim 9, wherein the silicon-germanium has a germanium concentration greater than 35%.

11. The method of claim 9, wherein the silicon-germanium deposit has a thickness in the range from 4 to 25 nm.

12. The method of claim 9, wherein the hydrogen is introduced into the epitaxy reactor, at a flow rate in the range from 40 to 50 standard liters per minute, the dichlorosilane is introduced at a flow rate in the range from 0.06 to 0.3 standard liter per minute, the germane is introduced at a flow rate in the range from 0.006 to 0.03 standard liter per minute, and the hydrogen chloride is introduced at a flow rate in the range from 0.01 to 0.1 standard liter per minute.

13. The method of claim 12, wherein the dichlorosilane is introduced at a flow rate in the order of 0.1 standard liter per minute.

14. The method of claim 12, wherein germane is introduced at a flow rate in the order of 0.01 standard liter per minute.

15. The method of claim 12, wherein hydrogen chloride is introduced at a flow rate in the order of 0.06 standard liter per minute.

16. The method of claim 9, wherein the first temperature value is in the range from 650 to 750° C.

17. The method of claim 9, wherein the second temperature value is in the range from 400 to 650° C.

18. The method of claim 9, wherein the silicon or silicon-germanium is boron-doped in situ by using diborane.

19. The method of claim 9, wherein the silicon or the silicon-germanium is doped in situ with a negative-type dopant by using phosphine or arsine.

20. The method of claim 9, wherein a silicon-germanium-carbon alloy is deposited by epitaxy.

21. A structure obtained by implementing the method of claim 1.

22. The structure of claim 21, wherein the structure comprises a silicon-germanium deposit on a silicon surface having a lateral dimension smaller than 40 nm of a substrate, said deposit having a lateral dimension smaller than 40 nm and being faceted, with no rounding of the facet angles.
